(19) United States
(12) Patent Application Publication
(10) Pub. No.: US 2026/0167481 A1
(43) Pub. Date: Jun. 18, 2026

(54) MEMS Device Having Reduced Package Size

(71) Applicant: InvenSense, Inc., San Jose, CA (US)

(72) Inventors: Vijay Wakharkar, Los Gatos, CA (US); Camillo Pilla, Castiglione del Lago (IT); Roberto Martini, Milano (IT)

(21) Appl. No.: 19/392,936

(22) Filed: Nov. 18, 2025

Related U.S. Application Data
(60) Provisional application No. 63/733,247, filed on Dec. 12, 2024.

(51) Int. Cl. B81B 7/00; B81C 1/00

(52) U.S. Cl. CPC B81B 7/007; B81C 1/00301; B81B 2207/012; B81C 2203/0792

(57) ABSTRACT

A microelectromechanical systems (MEMS) device and methods for its fabrication are disclosed. The MEMS device includes a processing layer having processing circuitry and a plurality of bond pads and a MEMS layer bonded to the processing layer. Signals generated by a MEMS component are processed by the circuitry and routed through a plurality of electrical connections extending vertically from the bond pads to a redistribution layer and a plurality of solderable pads that define external contact points for direct electrical bonding to external circuitry. The MEMS and processing layers, along with the electrical connections, are encapsulated in an overmold with the solderable pads exposed at a substantially planar package surface.

### CROSS REFERENCE TO RELATED APPLICATIONS

This application claims priority to U.S. Provisional Application No. 63/733,247 filed on Dec. 12, 2024, titled “Package Architecture for MEMS Devices that Minimizes X-Y Footprint & Z Height,” the disclosure of which is incorporated herein by reference in its entirety as though set forth in full.

### BACKGROUND

Numerous items such as smartphones, smart watches, tablets, automobiles, aerial drones, appliances, aircraft, exercise aids, and game controllers utilize sensors during their operation (e.g., motion sensors, pressure sensors, temperature sensors, etc.). In commercial applications, microelectromechanical system (MEMS) devices or sensors such as accelerometers and gyroscopes capture complex movements and determine orientation or direction. For example, smartphones are equipped with accelerometers and gyroscopes to augment navigation systems that rely on Global Positioning System (GPS) information. In another example, an aircraft determines orientation based on gyroscope measurements (e.g., roll, pitch, and yaw) and vehicles implement assisted driving to improve safety (e.g., to recognize skid or roll-over conditions).

As more products incorporate MEMS technology for a wide variety of applications, MEMS devices must integrate with numerous form factors in miniaturized devices. A MEMS device may typically include numerous components and systems such as microelectromechanical components, analog and digital circuitry, and other associated processing circuitry for calculating outputs based on signals associated with the microelectromechanical components. In addition, these components need to be protected from the external environment, packaged, and interconnected with other components. The resulting MEMS device, although extremely small, may take up valuable space within the end-use device.

### SUMMARY

According to an example embodiment, a microelectromechanical sensor (MEMS) device includes a processing layer having processing circuitry and multiple bond pads that each receive a processed signal from the circuitry. A MEMS layer is bonded to the processing layer and defines a cavity containing at least one movable MEMS component. The processing circuitry generates a signal based on the response of the movable MEMS component to an external force, and this processed signal is provided to one of the bond pads. A plurality of electrical connections extend vertically from the bond pads to the upper surface of the MEMS layer, and a redistribution layer provides conductive paths that extend laterally across the MEMS layer, each connected to one of the electrical connections. A plurality of solderable pads form external solderable contact points, each connected to one of the conductive paths such that a first solderable pad receives the processed signal. An overmold encapsulates the MEMS layer, the processing layer, and the electrical connections, with the upper surfaces of the solderable pads left exposed to define a package surface configured for direct bonding to corresponding pads of an external device.

In another example embodiment, a method for fabricating a microelectromechanical sensor (MEMS) device includes providing a processing layer that contains processing circuitry and multiple bond pads, each configured to receive a processed signal from the circuitry. A MEMS layer is coupled to the processing layer, the MEMS layer defining a cavity that includes at least one movable MEMS component. A plurality of electrical connections are then formed, each extending vertically from a respective bond pad to an upper surface of the MEMS layer. A redistribution layer is formed on the upper surface of the MEMS layer, the redistribution layer including multiple conductive paths that extend laterally across a horizontal portion of the MEMS layer, each path connected to one of the electrical connections. A plurality of solderable pads are formed on the redistribution layer, defining external solderable contact points, each connected to a corresponding conductive path. An overmold is then formed to encapsulate the MEMS layer and the processing layer, while leaving the upper surfaces of the solderable pads exposed. Finally, the upper surface of the overmold is planarized to define a package surface incorporating the overmold and solderable pads for direct mounting to external circuitry.

In another example embodiment, a method for fabricating a microelectromechanical sensor (MEMS) device includes providing a processing layer that comprises processing circuitry and multiple bond pads, each configured to receive a processed signal from the circuitry. A MEMS layer is coupled to the processing layer, the MEMS layer defining a cavity that contains at least one movable MEMS component. An overmold is then formed to encapsulate both the MEMS layer and the processing layer. Vias are created through the overmold to provide access to the bond pads, and a plurality of electrical connections are formed, each extending vertically from a respective bond pad through a corresponding via to an upper surface of the overmold. A redistribution layer is then formed on the upper surface of the overmold. The redistribution layer includes multiple conductive paths that extend laterally across the overmold, with each path connected to one of the electrical connections. A plurality of solderable pads are formed on the redistribution layer. The solderable pads define external solderable contact points, each connected to one of the conductive paths.

### BRIEF DESCRIPTION OF DRAWINGS

The above and other features of the present disclosure, its nature, and various advantages will be more apparent upon consideration of the following detailed description, taken in conjunction with the accompanying drawings in which:

FIG. 1 shows an illustrative MEMS system in accordance with an embodiment of the present disclosure;

FIG. 2 depicts a schematic section view of an exemplary MEMS device in accordance with an embodiment of the present disclosure;

FIG. 3 depicts a perspective view of an exemplary MEMS device in accordance with an embodiment of the present disclosure;

FIG. 4 depicts a perspective view of an exemplary MEMS device with several layers removed in accordance with an embodiment of the present disclosure;

FIGS. 5A-5F depict schematic illustrations of an exemplary MEMS device at various stages of fabrication in accordance with an embodiment of the present disclosure;

FIG. 6 depicts a perspective exploded view of an exemplary MEMS device in accordance with an embodiment of the present disclosure;

FIGS. 7A-7E depict schematic illustrations of an exemplary MEMS device at various stages of fabrication in accordance with an embodiment of the present disclosure;

FIG. 8 depicts exemplary steps of an exemplary fabrication process for a MEMS device in accordance with an embodiment of the present disclosure;

FIG. 9 depicts exemplary steps of another exemplary fabrication process for a MEMS device in accordance with an embodiment of the present disclosure; and

FIG. 10 depicts exemplary steps of another exemplary fabrication process for a MEMS device in accordance with an embodiment of the present disclosure.

### DETAILED DESCRIPTION

Although the present disclosure will be described in the context of MEMS devices, it will be understood that embodiments herein may be applied to other sensors and components that are integrated utilizing chip-scale or wafer-level techniques, such as a magnetic sensor including integrated processing such as an ASIC, for example, implementing a tunnel magnetoresistance sensor. In an example of a MEMS device, the MEMS device is fabricated using semiconductor processes and includes a plurality of stacked layers that are bonded together. One or more of the layers include microelectromechanical components that respond to a force of interest (e.g., linear acceleration, angular velocity, pressure, magnetism, ultrasonic forces, etc.) by moving in response to the force and measuring the movement to generate output signals and/or modifying electrical signals in response to the force. The microelectromechanical components are packaged within the other layers of the MEMS device. One or more of the layers of the MEMS device includes circuitry that processes signals resulting from the microelectromechanical components (e.g., filtering, scaling, etc.). The resulting output signals are provided to an external surface of the MEMS device to be transmitted to other components of the end-use device for additional processing. In addition, the MEMS device also receives input signals (e.g., power signals, ground, clock signals, control signals for modifying register values, data lines for communicating, etc.). These input signals are received via an external surface of the MEMS device.

The example embodiments provide a compact and reliable package for a MEMS device. As noted above, MEMS devices detect conditions such as movement, vibration, or pressure, and are used in products such as phones, cars, medical tools, and industrial equipment. A processing layer interprets the movement of the MEMS components and prepares signals for use by another component of the end use device. Internal bond pads of the MEMS device are located at a surface of the processing layer (e.g., on an upper surface of the processing layer) to provide electrical contact points for signal transmission via other components of the MEMS device. A MEMS layer is attached to the processing layer and includes movable MEMS components (e.g., one or more proof masses) of the MEMS device that respond to a force of interest and provide a signal to the processing layer (e.g., such as by changes in capacitance based on the locations of the proof masses relative to sense electrodes of or coupled to the processing layer). Electrical connections and a redistribution layer can form traces that transmit signals from the bond pads to the outside surface. Solderable pads can be located on top of these traces as flat metal features where the MEMS device can be directly joined to another device such as through a solder reflow process. The MEMS device can be enclosed in a protective overmold that protects the respective layers and electrical connections. The overmold can be deposited, polished or ground down so that the solderable pads are exposed substantially coplanar with the upper surface of the MEMS device to provide a flat, low-profile package that can be mounted directly onto external circuits.

The disclosure provides a microelectromechanical systems (MEMS) device and various methods of fabricating it using advanced semiconductor packaging techniques. The MEMS device is composed of multiple stacked layers bonded together, including a layer with miniature mechanical components that physically respond to forces such as motion, or vibration, and another layer containing electronic circuitry that interprets these responses. When exposed to a force, the movable MEMS components generate electrical signals that are processed by internal circuitry of the processing layer and transmitted to solderable pads at an external surface for connection to other circuitry of an end-use device. The device also receives input signals such as power, timing, and control information from the external circuitry. The design achieves this complex sensing and processing capability within a highly integrated and compact structure that can be directly connected to other circuits or devices.

The embodiments described below benefit from how the MEMS device is packaged and electrically connected. Traditional MEMS devices often rely on separate packages or fragile wire bonds to connect internal circuits to external contacts, which increases size, cost, and mechanical vulnerability. In contrast, the disclosed arrangement routes electrical connections vertically through the MEMS structure and laterally across redistribution layers, formed as thin metal pathways on insulating layers, which lead to solderable pads on the upper surface. These pads serve as robust external contact points that can be directly joined to external circuitry without requiring additional packaging, solder balls, or wire bonds. The entire structure, including the MEMS and processing layers, can be encapsulated within a protective overmold, leaving only the solderable pads exposed on a smooth, planar surface. This configuration produces a low-profile, durable, and easily mountable MEMS package.

By eliminating intermediate package layers and delicate bonding wires, the MEMS device achieves a smaller size, reduced height, and lower manufacturing complexity. The continuous conductive routing through redistribution structures minimizes the number of interfaces, thereby improving electrical reliability and signal integrity. The planarized surface provided by the exposed solderable pads allows direct surface mounting (such as flip-chip bonding) to printed circuit boards or modules, enhancing mechanical stability and heat dissipation. The overmold encapsulation provides environmental protection while maintaining electrical isolation between conductive features. These improvements collectively reduce manufacturing costs, improve durability, and enable MEMS devices to be integrated into smaller and more demanding environments, such as compact consumer electronics, automotive safety systems, and precision medical instruments.

The disclosure also presents multiple fabrication variants demonstrating flexibility in design. In one embodiment, electrical paths are formed directly on dielectric surfaces of the device. In another variant, conductive vias are formed through a peripheral extension of the MEMS layer to reach the upper surface. In yet another variant, vias are created through the overmold after encapsulation to establish vertical connections. Each of these embodiments provides transmission of signals from internal bond pads of the processing layer to external solderable contact pads while accommodating manufacturing constraints and performance goals. The embodiments provide simpler, more compact, and more robust MEMS packaging structures that integrate sensing, processing, and interconnection within a single planarized assembly.

The disclosed MEMS device offers advanced packaging and interconnect architecture that combines functional integration, mechanical protection, and simplified assembly. By routing signals through internal redistribution layers and exposing coplanar solderable contact points on the package surface, the device eliminates traditional limitations of size, fragility, and assembly complexity. This approach enables compact, high-performance MEMS sensors capable of reliable operation in applications where space, precision, and environmental durability are critical.

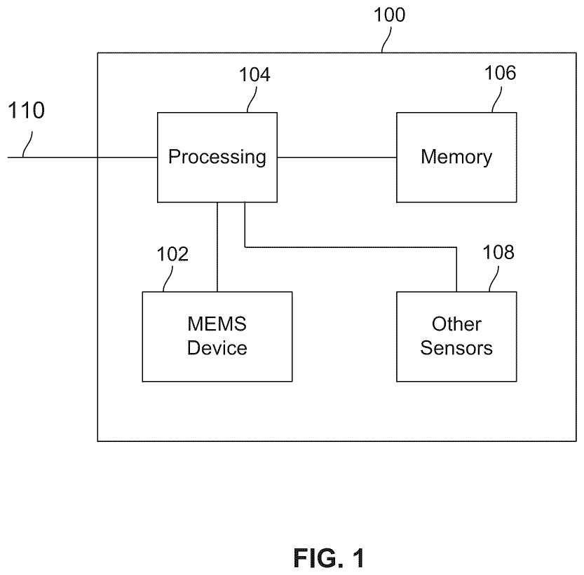

FIG. 1 depicts an exemplary motion sensing system 100 in accordance with some embodiments of the present disclosure. Although particular components are depicted in FIG. 1, it will be understood that other suitable combinations of sensors, processing components, memory, and other circuitry may be utilized as necessary for different applications and systems. In an embodiment as described herein, the motion sensing system may include at least a MEMS device 102 (e.g., a multi-axis MEMS inertial sensor including one or more MEMS gyroscopes and/or one or more MEMS accelerometers) and supporting circuitry, such as processing circuitry 104 and memory 106. In some embodiments, one or more additional sensors 108 (e.g., magnetic sensors, MEMS gyroscopes, MEMS accelerometers, MEMS microphones, MEMS pressure sensors, and a compass) may be included within the motion processing system 100 to provide an integrated motion processing unit (“MPU”) (e.g., including 3 axes of MEMS gyroscope sensing, 3 axes of MEMS accelerometer sensing, microphone, pressure sensor, and compass).

Processing circuitry 104 may include one or more components providing necessary processing based on the requirements of the motion processing system 100. In some embodiments, processing circuitry 104 may include hardware control logic that may be integrated within a chip of a sensor (e.g., on a substrate or cap of MEMS device 102 or other sensor 108, or on an adjacent portion of a chip to MEMS device 102 or other sensor 108) to control the operation of the MEMS device 102 or other sensors 108 and perform aspects of processing for the MEMS device 102 or other sensors 108. In some embodiments, the MEMS device 102 and other sensors 108 may include one or more registers that allow aspects of the operation of hardware control logic to be modified (e.g., by modifying a value of a register). In some embodiments, processing circuitry 104 may also include a processor such as a microprocessor that executes software instructions that are stored in memory 106. The microprocessor may control the operation of the MEMS device 102 by interacting with the hardware control logic, and process signals received from MEMS device 102. The microprocessor may interact with other sensors in a similar manner. In some embodiments, some or all of the functions of the processing circuitry 104, and in some embodiments, of memory 106, may be implemented on an application specific integrated circuit (“ASIC”) and/or a field programmable gate array (“FPGA”).

Although in some embodiments (not depicted in FIG. 1), MEMS device 102 or other sensors 108 may communicate directly with external circuitry (e.g., via a serial bus or direct connection to sensor outputs and control inputs), in one embodiment, processing circuitry 104 may process data received from MEMS device 102 and other sensors 108 and communicate with external components via communication interface 110 (e.g., a SPI or I2C bus, or in automotive applications, a controller area network (CAN) or Local Interconnect Network (LIN) bus). Processing circuitry 104 may convert signals received from MEMS device 102 and other sensors 108 into appropriate measurement units (e.g., based on settings provided by other computing units communicating over the communication bus 110) and perform more complex processing to determine measurements such as orientation or Euler angles, and in some embodiments, to determine from sensor data whether a particular activity (e.g., walking, running, braking, skidding, rolling, etc.) is taking place.

In some embodiments, certain types of information may be determined based on data from multiple MEMS devices, in a process that may be referred to as sensor fusion. By combining information from a variety of sensors it may be possible to accurately determine information that is useful in a variety of applications, such as image stabilization, navigation systems, automotive controls and safety, dead reckoning, remote control and gaming devices, activity sensors, 3-dimensional cameras, industrial automation, and numerous other applications.

Each MEMS device or a combination of MEMS devices may include microelectromechanical components (e.g., of a MEMS layer) within a cavity. For example, a MEMS layer may include microelectromechanical components that respond to the force of interest in a manner that generates signals that are processed by the MEMS device (e.g., by circuitry within a processing layer such as a CMOS substrate layer or by a bonded processing layer of the MEMS device) to generate output signals such as analog or digital signals representing sensed motion, status signals, data signals, and control signals. The MEMS device is also supplied with input signals from external devices such as power signals, ground, clock signals, register control signals, and data lines.

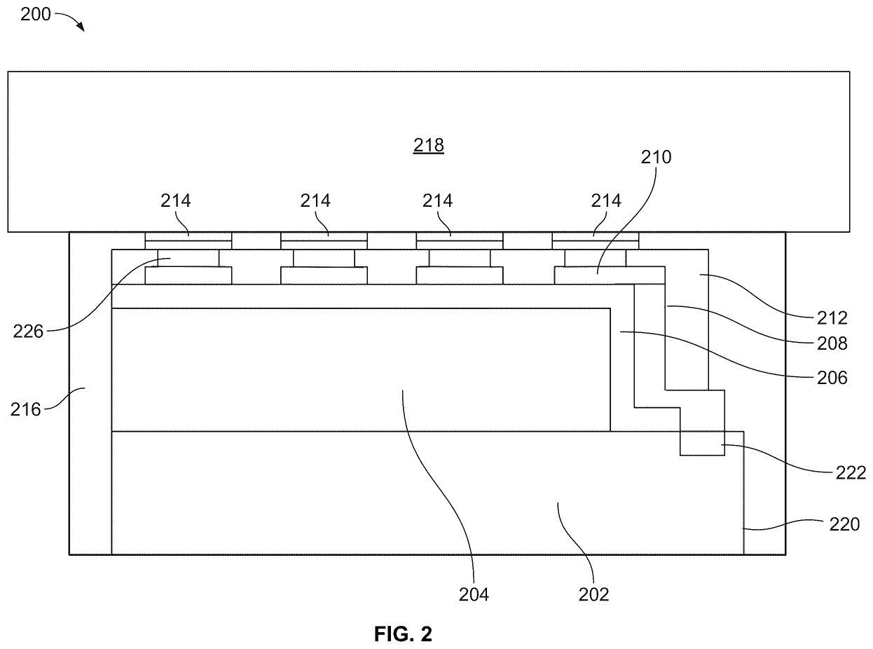

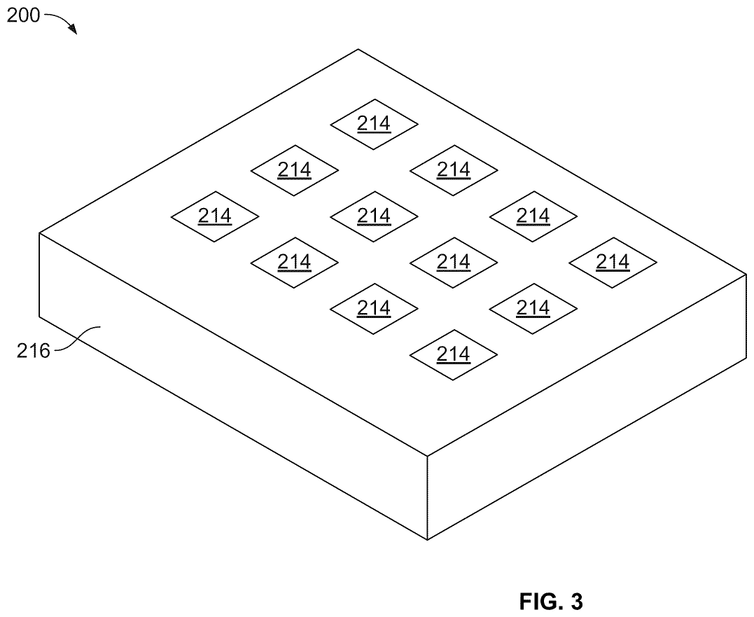

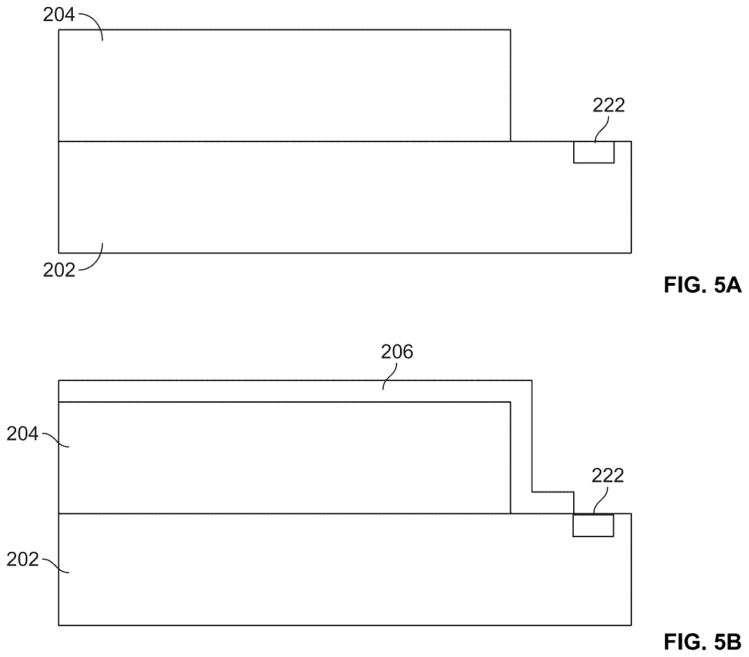

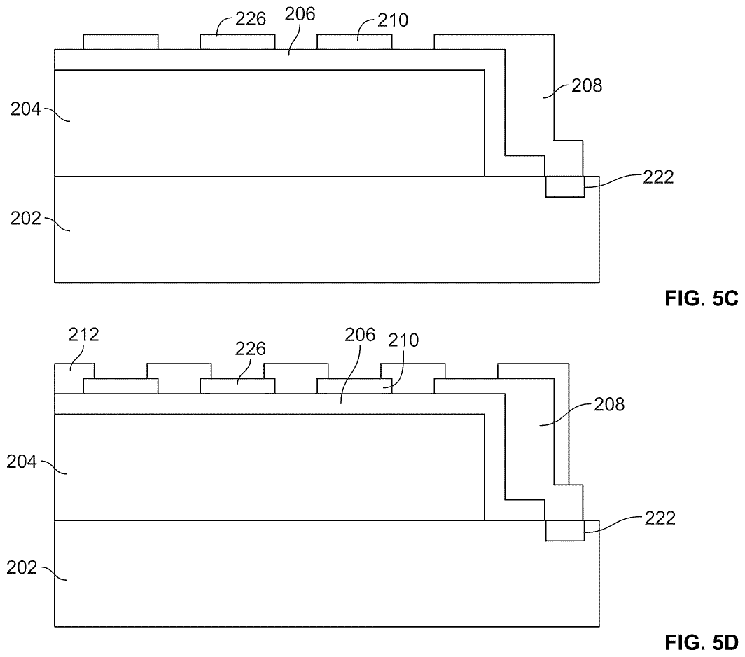

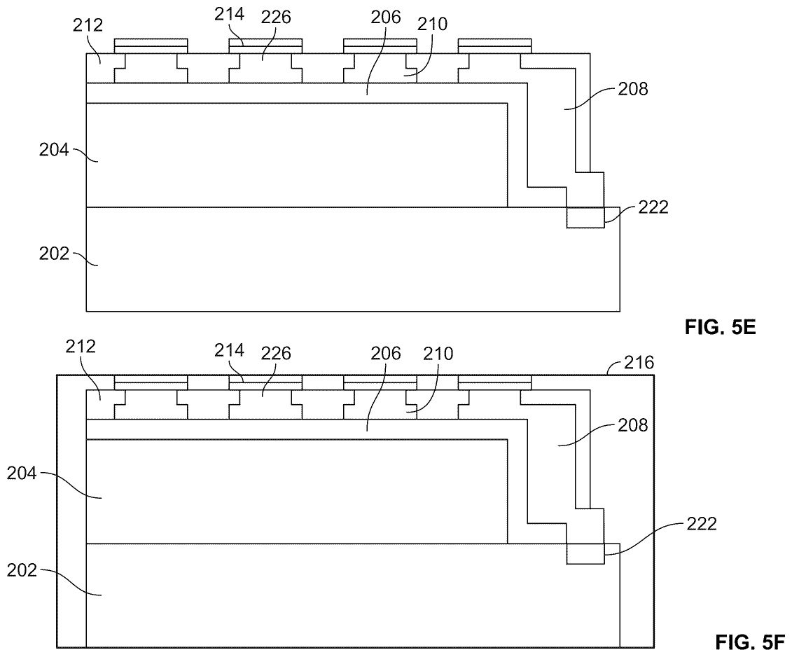

Although FIGS. 2-10 will be described in the context of a MEMS sensor, it will be understood that embodiments herein may be applied to other sensors and components such as accelerometers, gyroscope, magnetic sensors. FIGS. 2-4 depict an exemplary MEMS device 200 having continuous portions of conductive material between connection points in accordance with some embodiments of the present disclosure and FIGS. 5A-5F depict MEMS device 200 at various stages in the fabrication process. For example, metallization features can be formed in a single plating step (or sequence) that extend both vertically and laterally. Although a MEMS device may include a variety of configurations fabricated with different semiconductor layers, in the exemplary embodiment of FIGS. 2-4, MEMS device 200 may be an inertial MEMS sensor including a processing layer 202 (e.g., a CMOS layer), a MEMS layer 204, a first insulating layer 206, electrical connections 208, a redistribution layer 210, a second insulating layer 212, solderable pads 214, and an overmold 216. An end use device 218 is illustrated electrically connected to solderable pads 214. In this arrangement, the layers are integrated to form a compact device in which signals from the processing layer 202 are routed upward and outward through redistribution structures, enabling external connection at solderable pads 214 without intermediate bonding wires. Overmold 216 can provide mechanical and environmental protection while leaving the solderable pads accessible at a substantially planar package surface. The overall stack height may be tailored by selecting thicknesses for the MEMS layer, processing layer, the insulating layers, redistribution metal, and overmold to meet target Z-height constraints of the end application, while maintaining adequate mechanical rigidity and thermal conduction pathways through the mold compound and metal features.

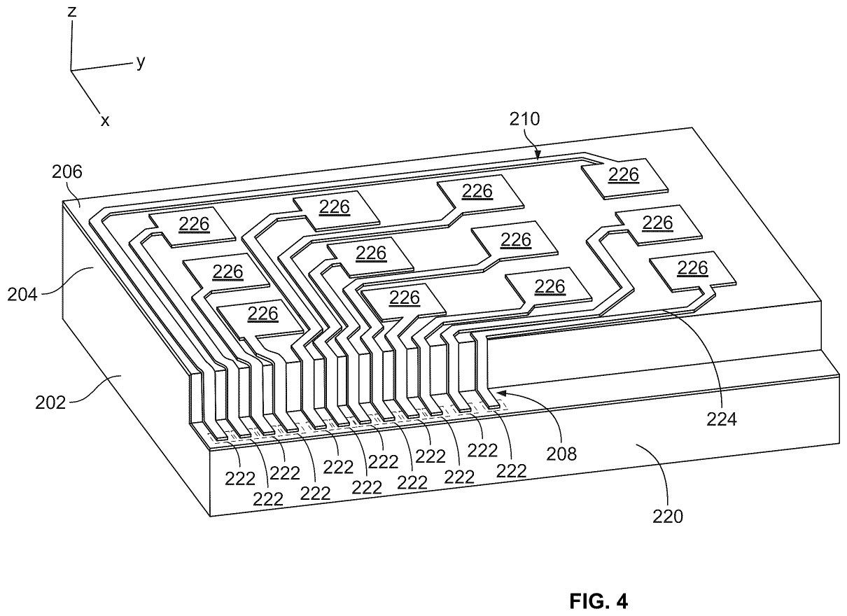

In an embodiment, MEMS layer 204 can be bonded to processing layer 202 and define a cavity including at least one movable MEMS component (e.g., electromechanical proof masses). In the example embodiment shown in FIGS. 2-4, MEMS layer 204 does not depict a separate cap layer, although it will be understood that in some embodiments the MEMS layer 204 can include a MEMS handle including the proof masses and that is bonded to the processing layer, and be bonded on the opposite side to a cap layer that collectively forms the cavity housing the proof mass and that provides the upper surface of the MEMS device and MEMS layer. Movement of the electromechanical components may be sensed (e.g., by capacitive sensing, piezoelectric sensing, etc.) and signals corresponding to the movement may be routed on and/or through MEMS device 200 to an external surface thereof. Processing layer 202 can include processing circuitry that processes a signal based on a response of the movable MEMS component to a force of interest. In the exemplary embodiment of FIGS. 2-4, the signals may be routed through processing layer 202 to bond pads 222 on an external shelf 220 of processing layer 202. In some embodiments, processing such as filtering, scaling, A/D conversion, and more complex computations (e.g., orientation, etc., as performed by an embedded ASIC) may be performed within MEMS device 200 (e.g., within processing layer 202). The sensed and/or processed outputs may be provided to external connection points or bond pads 222, which may be located on shelf 220 of processing layer 202. Shelf 220 can extend laterally beyond the other layers of MEMS device 200 (in the x-direction in FIG. 4). Although bond pads 222 can be located and configured in a variety of suitable shapes and patterns, in an embodiment bond pads 222 can each have a uniform same size and shape and be aligned with one another in a row along a length of the shelf of the processing layer 202. The geometry of shelf 220 enables access to bond pads 222 for vertical routing. In some configurations, bond pads 222 may alternatively be arranged in staggered rows or a two-dimensional grid to increase input/output density while maintaining compatibility with redistribution patterns.

In an embodiment of the present disclosure, first insulating layer 206 (e.g., a WPR photoresist) may overlay portions of processing layer 202 (e.g., shelf 220 of processing layer 202) and MEMS layer 204 (e.g., an external-facing portion of MEMS layer 204). In some embodiments, first insulating layer 206 may include multiple layers and/or different materials at different portions of the external surfaces of processing layer 202 and MEMS layer 204, or in some embodiments, other layer types may be included with or substituted for first insulating layer 206. First insulating layer 206 may extend over and conform to both horizontal and vertical surfaces, creating a dielectric cover for those surfaces. Patterned openings may be located in first insulating layer 206 to permit selective contact to bond pads 222 while keeping other areas electrically isolated. Suitable materials include polymer dielectrics such as polyimide (PI), benzocyclobutene (BCB), or PBO, or inorganic dielectrics such as SiO₂ or SiN.

Electrical connections 208 can each be connected to one of bond pads 222 and extend vertically and horizontally to a redistribution layer 210 at an upper surface of MEMS layer 204. Redistribution layer 210 can include a plurality of conductive paths 224 extending laterally across a horizontal portion on the upper surface of the first insulating layer 206 at the upper surface of MEMS layer 204. Each conductive path 224 can be connected to one of electrical connections 208. In an exemplary embodiment of the particular layers and configuration of MEMS device 200, continuous portions of material can form electrical connections 208 and redistribution layer 210. In this example, conductive paths 224 form redistribution layer 210 (referred to collectively as “redistribution layer 210” in this example) and can extend laterally from the electrical connections 208 (e.g., each of which is connected to a respective bond pad 222 located along an external surface of the shelf of processing layer 202). Exemplary materials for the continuous portions of material include Copper (Cu), Gold (Au), Nickel (Ni), and Aluminum (Al).

In the example shown, bond pads 222 extend in a row along the y-direction. Electrical connections 208 can extend in the x-direction to a vertically extending external surface of MEMS layer 204 and continue vertically along the external surface of MEMS layer 204. Electrical connections 208 can then proceed in the x-direction, y-direction, or some combination of the x-direction and γ-direction to the redistribution layer 210 at the upper surface of the MEMS layer 204, with each individual conductive path 224 of the redistribution layer 210 terminating at an electrical connection location 226.

A second insulating layer 212 (e.g., another WPR) may overlay first insulating layer 206, electrical connections 208, and portions of redistribution layer 210 formed on first insulating layer 206. As seen in FIG. 2, second insulating layer 212 can be patterned with openings exposing regions of redistribution layer 210 at electrical connection locations 226 for connection with solderable pads 214. Like first insulating layer 206, in some embodiments, second insulating layer 212 may include multiple layers and/or different materials at different portions thereof, or in some embodiments, other layer types may be included with or substituted for second insulating layer 212 . . . . Second insulating layer 212 can serve as a protective passivation coating, ensuring that redistribution traces remain electrically isolated from each other and from overmold 216. Materials for second insulating layer 212 may include photosensitive polyimide or PBO, which can be patterned with high resolution to expose only desired contact regions.

Electrical connection locations 226 can be arranged in a grid pattern with a corresponding grid pattern arrangement of solderable pads 214 located on electrical connection locations 226 of redistribution layer 210. Solderable pads 214 can each be the same size and shape (e.g., square). Exemplary materials for solderable pads 214 include Copper (Cu), Gold (Au), Nickel (Ni), and Aluminum (Al). Solderable pads 214 may be formed as metallization stacks, such as Cu/Ni/Au, to improve solderability and corrosion resistance. In one example, solderable pads 214 can form an underbump metallization. Coplanarity across the grid array can be controlled within about 5-10 microns to ensure reliable solder reflow.

Overmold 216 can cover or encapsulate all components of the MEMS device 200 except for the upper surfaces of the solderable pads 214 (e.g., including processing layer 202, MEMS layer 204, electrical connections 208, redistribution layer 210). Exemplary materials for overmold 216 include epoxy An upper surface of each solderable pad 214 can be exposed and substantially coplanar with an upper surface of overmold 216. As a result, a substantially planar package surface can be provided for direct bonding to corresponding pads of an external device (e.g., end use device 218). The term “substantially” is understood by those skilled in the art to mean suitable for direct bonding. By way of non-limiting example, a substantially planar or substantially coplanar can include deviations, such as 5-10 microns. Planarization processes, such as grinding, can be employed after molding to expose solderable pads 214 flush with the surrounding overmold 216.

In comparison to conventional MEMS devices, the exemplary embodiment of FIGS. 2-4 does not require an additional package layer or bonding thereto for electrical or physical connection to the external components. Removing the intermediate package layer reduces the overall size of the packaging of the MEMS device, as well as reducing cost and removing fabrication steps. In addition, because the continuous portions of material are fabricated directly over the external non-conductive surfaces of the layers of the MEMS device, there is no need for wire bond connections between any layers of the MEMS sensor. Further, the continuous portions of material are patterned and located such that they will not come into contact with each other and are unlikely to come into contact with other external conductive components. The reduced size and weight of the MEMS device of FIGS. 2-4 allows the MEMS device to be placed in smaller environments with more precision. Further, the direct connection by the solderable pads securely attaches the MEMS device to the other components. In combination with the reduced height and profile of the MEMS device, the forces imparted on the solder coupling are substantially reduced.

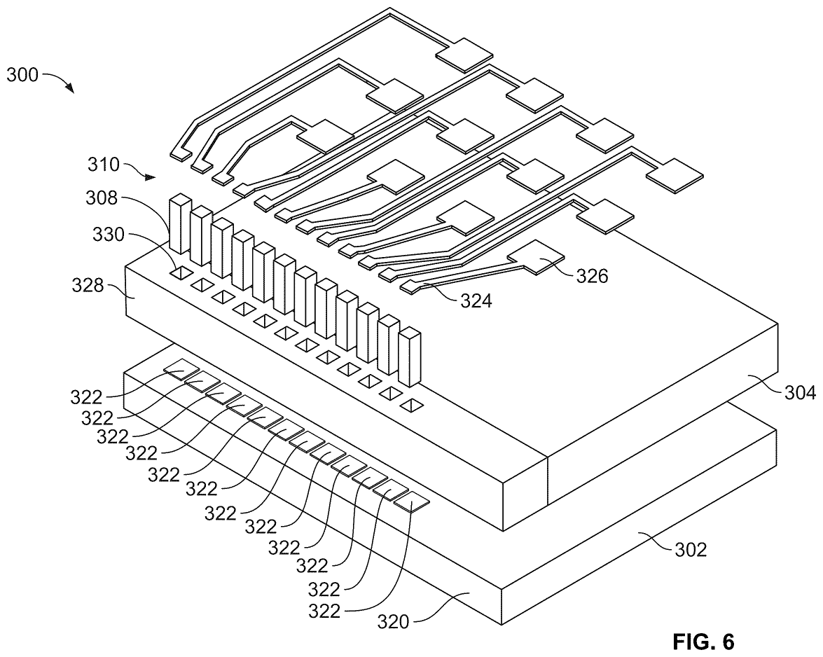

An alternate MEMS device 300 is shown in FIG. 6. MEMS device 300 may be generally similar to MEMS device 200. Accordingly, similar features will not be described in detail with the understanding that the description from MEMS device 200 applies, with exceptions noted below. Unlike shelf 220 extending beyond MEMS layer 204 in MEMS device 200, MEMS device 300 can include a MEMS layer 304 with a peripheral extension 328 that overlies shelf region 320 of processing layer 302. This geometry can reduce lateral redistribution layer span over open regions by providing an overlying structural surface, which may increase mechanical robustness and allow tighter vertical interconnect placement directly above the bond-pad row.

Vias 330 can be formed in peripheral extension 328, with vias 330 extending in a row aligned with bond pads 322. Vias 330 can be square as show in FIG. 6 measuring 50-100 microns or can be other shapes such as circular with a diameter 50-100 microns. A first insulating layer (not shown) can be formed over external (both horizontal and vertical) surfaces of processing layer 302 and MEMS layer 304 and can line vias 330. Electrical connections 308 can extend through each of vias 330 and be electrically connected to bond pads 322. Redistribution layer 310 can include conductive paths 324 that extend horizontally along first insulating layer (not shown) on an upper surface of MEMS layer 304 from electrical connections 308 to electrical connection locations 326. In some embodiments, 326 can be circular. In some embodiments, a passivation overcoat may be formed atop redistribution layer 310 with patterned windows at locations 326 to define solderable pad sites.

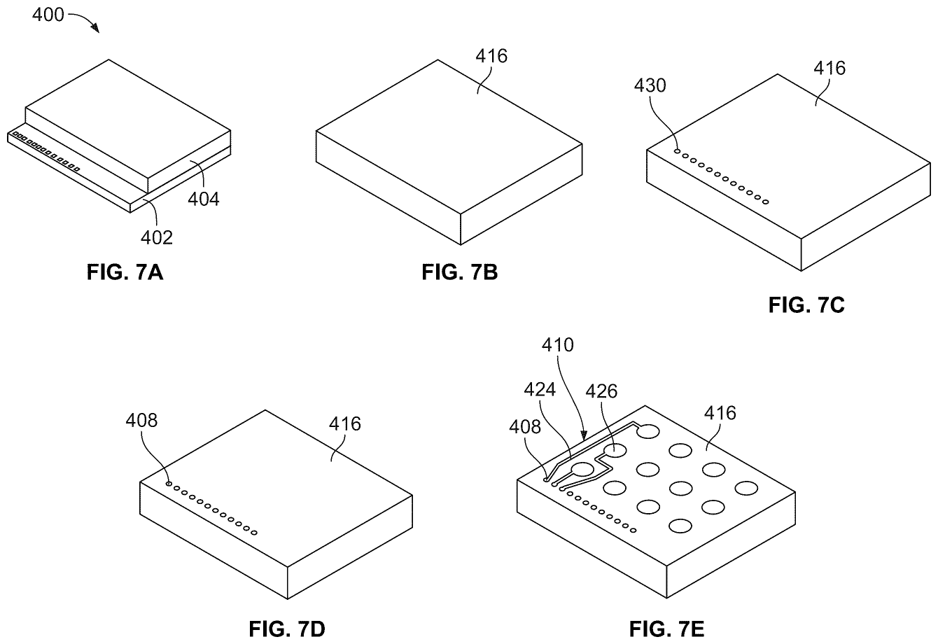

Another alternate MEMS device 400 is shown in FIGS. 7A-7E. MEMS device 400 may be generally similar to MEMS device 200. Accordingly, similar features will not be described in detail with the understanding that the description from MEMS device 200 applies, with exceptions noted below. As seen in FIG. 7A processing layer 402 and MEMS layer 404 can be generally similar to processing layer 202 and MEMS layer 204. A first insulating layer (not shown) can be formed like first insulating layer 206. As seen in FIGS. 7B and 7C, however, overmold 416 can be formed over processing layer 402 and MEMS layer 404 and vias 430 can be formed in overmold 416 (similar to vias 330 discussed above). Forming vias within an overmold allows redistribution to be realized predominantly in the mold plane, which can simplify trace routing over irregular topography and may improve environmental isolation of underlying silicon surfaces.

Vias 430 can extend in a row aligned with bond pads (not shown). A first insulating layer (not shown) can be formed over external (both horizontal and vertical) surfaces of processing layer 402 and MEMS layer 404 and can line vias 430. Alternatively, the first insulating layer can be omitted in view of the arrangement of overmold 416 isolating MEMS layer 404 from contacting electrical connections 408 or redistribution layer 410. Where the first insulating layer is omitted, the mold material and metallization stack may be selected for mutual compatibility to ensure adhesion and to prevent corrosion. For example, a thin adhesion/barrier layer may be deposited prior to metallization within via 430 to ensure conductor anchoring.

As seen in FIGS. 7D and 7E, electrical connections 408 can extend through each of vias 430 and be electrically connected to bond pads (not shown). Redistribution layer 410 can include conductive paths 424 that extend horizontally along first insulating layer (not shown) on an upper surface of MEMS layer 404 from electrical connections 408 to electrical connection locations 426.

In some embodiments, electrical connection locations 426 can be other shapes such as circular. In some embodiments, a solder-mask-defined (SMD) pad scheme is used at locations 426 to precisely control solderable area and reduce bridging risk during reflow. Alternatively, non-solder-mask-defined (NSMD) pads may be employed, depending on the target assembly process.

Each of these embodiments demonstrates different techniques for providing vertical and horizontal routing from bond pads on the processing layer to solderable pads accessible at the device surface. Depending on performance, cost, and form factor requirements, a device may incorporate a cap layer, metallized vias in a peripheral extension of the MEMS layer, or redistribution routing on an overmold dielectric. Each configuration can provide a low-profile, substantially coplanar package surface suitable for direct mounting to external circuitry while avoiding traditional wire-bonded interconnects.

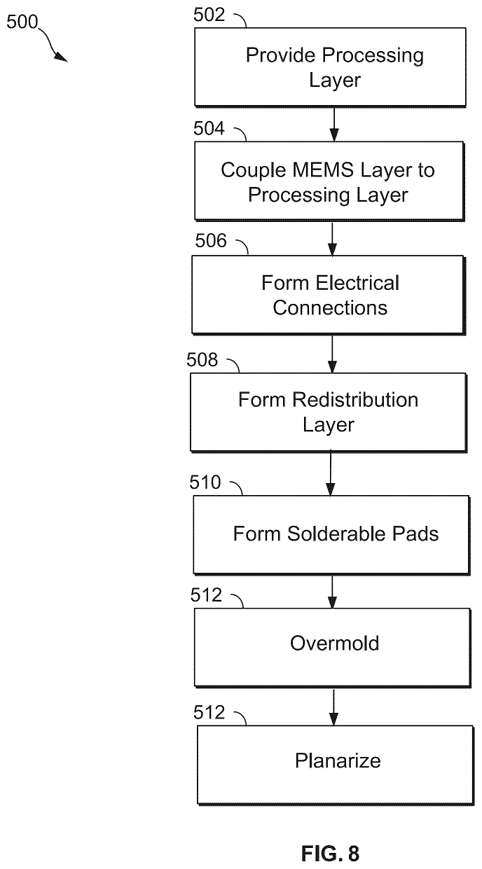

FIG. 8 illustrates an exemplary process 500 for fabricating a MEMS device in accordance with some embodiments of the present disclosure. The process 500 may be adapted for configurations using continuous redistribution connections (FIGS. 2-5F) or metallized vias through a peripheral extension of the MEMS layer (FIG. 6) or metallized vias through an overmold (FIGS. 7A-7E).

In step 502, a processing layer is provided. The processing layer may be a CMOS substrate or other integrated circuit layer that includes processing circuitry such as amplifiers, analog-to-digital converters, filters, and logic. A plurality of bond pads may be defined along a shelf portion of the processing layer, the bond pads formed of aluminum, copper, or aluminum-copper alloys. Passivation layers such as silicon dioxide, silicon nitride, or polymer dielectrics may be patterned to expose the bond pad surfaces.

In step 504, and with additional reference to FIG. 5A, MEMS layer 204 is coupled to processing layer 202. MEMS layer 204 may comprise a silicon wafer, silicon-on-insulator wafer, or glass wafer, bonded to the processing layer by direct oxide bonding, anodic bonding, or adhesive bonding. MEMS layer 204 defines a cavity including movable MEMS structures such as proof masses, springs, diaphragms, or resonant beams. In some embodiments, MEMS layer 204 may also include a cap layer overlying the cavity and an actuator layer that includes the moveable MEMS structure. In other embodiments, the overmold provides environmental sealing without a cap.

In step 506, and with additional reference to FIG. 5C, electrical connections 208 are formed from bond pads 222 toward the upper surface of MEMS layer 204. In one approach, continuous conductive traces are deposited over a first insulating layer 206 that is applied after the coupling in step 504 to conformally cover the processing layer and MEMS layer, as seen in FIG. 5B. First insulating layer 206 may be polyimide, PBO, benzocyclobutene, or a spin-on glass, and is patterned to expose the bond pads. A conductive seed layer such as Ti/Cu is sputtered, and copper or other metals are electroplated to form vertical and lateral redistribution portions that extend upward from the bond pads along dielectric covered surfaces. The plating may be performed in acid copper sulfate solutions at controlled current densities to ensure uniform coverage.

In another approach, a peripheral extension of the MEMS layer may overlie the bond pads, and vias are etched through the extension using deep reactive ion etching (DRIE) or laser drilling. The vias are lined with dielectric, followed by metallization with copper, nickel, or tungsten by electroplating, electroless plating, or chemical vapor deposition, thereby providing conductive passages from the bond pads to the top surface of the MEMS layer.

In step 508, and with additional reference to FIG. 5D, redistribution layer 210 is formed. For the dielectric-cover embodiment, redistribution layer 210 is patterned into lateral conductive traces extending across first insulating layer 206 and terminates at defined contact locations. For the via embodiment, the redistribution layer is deposited over the upper surface of the MEMS layer and electrically coupled to the metallized vias. Electroplating of copper is typically used to build redistribution traces to a thickness of about 2-10 microns. Optional capping with nickel and gold may be employed to reduce oxidation and enhance solderability. In some embodiments, the redistribution layer can be formed as a metallization within the upper surface of MEMS layer 204 in shallow trenches that are patterned and etched into the MEMS layer after the coupling of the MEMS layers, the sidewalls and floor can be lined with a dielectric to provide electrical isolation, and a conductive seed can be deposited followed by metal fill to form the conductive paths. Excess metal can be removed so that the metal remains substantially level with the adjacent MEMS surface. The inlaid traces can be positioned to receive vertical connections from metallized vias (e.g., those formed through a peripheral extension of the MEMS layer) and to terminate at defined contact locations for subsequent pad formation.

In step 510, and with additional reference to FIG. 5E, solderable pads 214 are formed. A second insulating layer 212, such as polyimide or photosensitive PBO, may be deposited and patterned to expose contact locations of redistribution layer 210. Under-bump metallization (UBM) stacks, such as Cu/Ni/Au, are deposited into the openings on an upper surface of the redistribution layer to form solderable pads. Solderable pads 214 may be square, rectangular, or circular, and may be arranged in a grid or linear pattern depending on system requirements. Each solderable pad 214 provides a robust external contact for mounting. Solder deposition (e.g., paste print or ball placement) may be deferred to the system-level assembly, as the disclosed device presents flat, coplanar metal pads.

In step 512, and with additional reference to FIG. 5F, an overmold is formed. The device may be mounted face-down on a temporary carrier, and an epoxy molding compound is deposited to encapsulate the MEMS layer, processing layer, redistribution layer, and insulating layers. Suitable overmold materials include silica-filled epoxy resins with low coefficients of thermal expansion. The overmold is cured and provides both mechanical protection and environmental sealing.

In step 514, planarization is performed if necessary. The carrier is removed, and the molded wafer is ground or polished until the solderable pads are exposed flush with the upper surface of the overmold. The resulting surface is substantially planar, with deviations typically less than 10 microns, allowing direct flip-chip mounting to external printed circuit boards or modules.

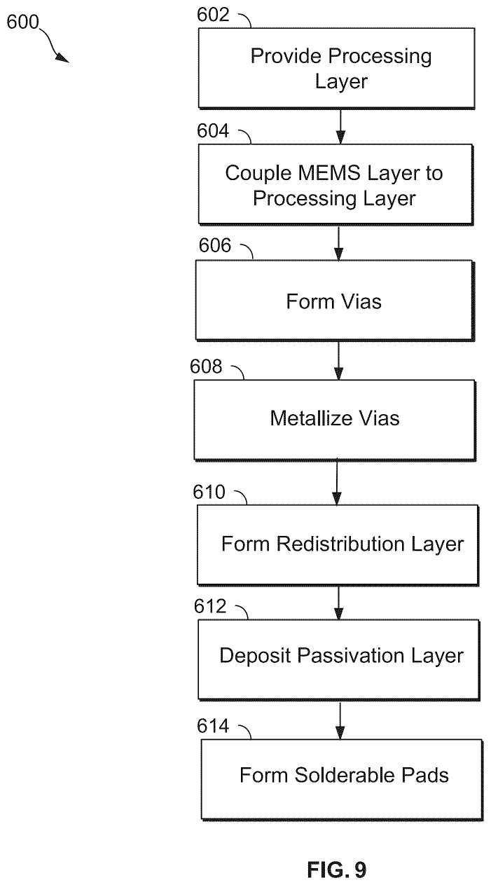

FIG. 9 illustrates an exemplary process 600 for fabricating MEMS device 300 from FIG. 6 (peripheral extension with metallized vias) in accordance with some embodiments of the present disclosure.

In step 602, processing layer 302 is provided that includes processing circuitry and a plurality of bond pads 322 disposed along shelf region 320. Bond pads 322 may be formed of aluminum, copper, or aluminum-copper alloys and are exposed through patterned passivation to enable later connection. In step 604, MEMS layer 304 including peripheral extension 328 is bonded to processing layer 302 so that peripheral extension 328 overlies shelf region 320 containing bond pads 322. The bonding may be accomplished by direct oxide bonding, anodic bonding, or adhesive bonding, with alignment features ensuring registration between the peripheral extension and the underlying bond pads.

In step 606, vias 330 are formed through peripheral extension 328 aligned with the plurality of bond pads 322. Vias 330 may be produced by deep reactive ion etching (DRIE) or laser drilling. A dielectric liner is deposited to electrically isolate the via surfaces from the peripheral extension, and the via openings are cleaned to expose the bond pad surfaces. In step 608, vias 330 are metallized to form electrical connections 308 extending from bond pads 322 to the upper surface of MEMS layer 304. Metallization may include deposition of an adhesion/barrier layer (e.g., Ti, TiW, or Cr) followed by copper or other suitable conductor fill by electroplating or electroless deposition. Overburden removal and light planarization may be performed to present clean via landings.

In step 610, redistribution layer (RDL) 310 is formed over the upper surface of MEMS layer 304. RDL 310 is patterned to provide lateral conductive traces 324 that extend from metallized vias 308/330 to defined electrical connection locations 326. RDL 310 may be copper or aluminum, deposited by sputtering and plating through patterned resist or by lift-off. Line width and spacing are selected to satisfy current-carrying, isolation, and routing-density requirements. In step 612, an upper passivation layer is deposited over redistribution layer 310 and patterned with openings at the electrical connection locations 326. Suitable passivation materials include polyimide, PBO, silicon dioxide, or silicon nitride. The openings define sites for external contacts and protect adjacent RDL features from environmental exposure. In step 614, solderable pads are formed within the passivation openings by depositing an under-bump metallization (UBM) stack (e.g., Cu/Ni/Au or Ni/Pd/Au). The solderable pads present flat, robust external contact surfaces suitable for direct mounting.

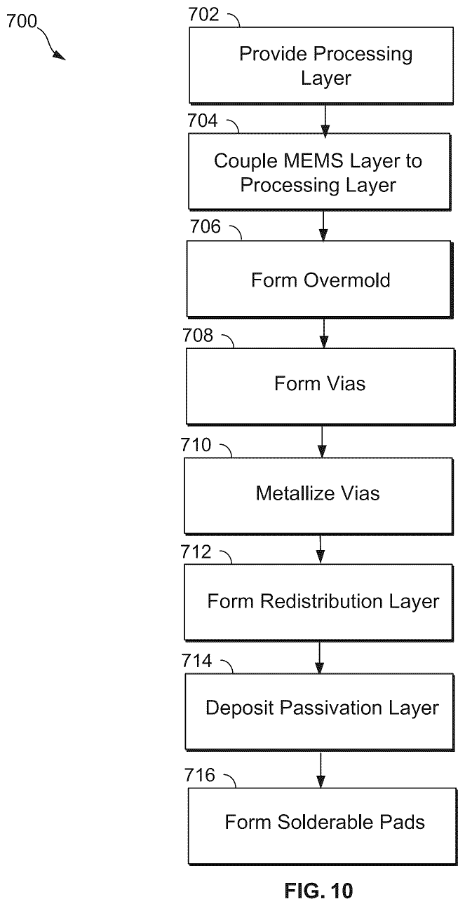

FIG. 10 illustrates an exemplary process 700 for fabricating MEMS device 400 shown in FIGS. 7A-7E (overmold vias with post-mold redistribution) in accordance with some embodiments of the present disclosure. In step 702, processing layer 402 with processing circuitry and bond pads is provided. In step 704, and with additional reference to FIG. 7A, processing layer 402 is coupled to MEMS layer 404 defining a cavity with at least one movable MEMS component. Bonding may be achieved by direct oxide bonding, anodic bonding, or adhesive bonding with appropriate alignment. In step 706, and with additional reference to FIG. 7B, overmold 416 is formed to encapsulate processing layer 402 and MEMS layer 404, creating a protective dielectric body above the device stack. The overmold composition and cure profile are selected to limit residual stress and to support subsequent lithographic processing on its upper surface.

In step 708, and with additional reference to FIG. 7C, vias 430 are formed through overmold 416 to the underlying bond pads of the processing layer. Vias 430 may be created by laser drilling, plasma etching, or mechanical drilling, followed by cleaning to ensure reliable metallurgical contact to the exposed pads. A dielectric liner can be deposited as needed to isolate conductor surfaces from the overmold material. In step 710, and with additional reference to FIG. 7D, the overmold vias 430 are metallized to create vertical electrical connections 408. Metallization may include deposition of an adhesion/barrier layer and conductor fill by electroplating or electroless deposition.

In step 712, and with additional reference to FIG. 7E, redistribution layer 410 is formed directly on the upper surface of overmold 416, with traces 424 extending laterally from the metallized vias 408/430 to defined electrical connection locations 426. Redistribution layer 410 may be copper patterned by photoresist imaging and plating. In step 714, an upper passivation layer is deposited over the redistribution layer and patterned with openings at terminal locations. Passivation materials may include polyimide, PBO, silicon dioxide, or silicon nitride. The passivation insulates and protects the redistribution layer while defining precise windows for external contacts. In step 716, solderable pads are formed at the passivation openings using an underbump metallization stack (e.g., Cu/Ni/Au or Ni/Pd/Au). The metal buildup is controlled to achieve the desired pad thickness and planarity relative to the surrounding passivation surface.

The foregoing description includes exemplary embodiments in accordance with the present disclosure. These examples are provided for purposes of illustration only, and not for purposes of limitation. It will be understood that the present disclosure may be implemented in forms different from those explicitly described and depicted herein and that various modifications, optimizations, and variations may be implemented by a person of ordinary skill in the present art, consistent with the following claims.

What is claimed is:

1. A microelectromechanical sensor (MEMS) device, comprising:
a processing layer including processing circuitry and a plurality of bond pads that each receive a processed signal from the processing circuitry;
a MEMS layer bonded to the processing layer and defining a cavity including at least one movable MEMS component, wherein the processing circuitry processes a signal based on a response of the at least one movable MEMS component to an external force, and wherein the processed signal is provided to a first bond pad of the plurality of bond pads;
a plurality of electrical connections, each of the plurality of electrical connections connected to one of the plurality of bond pads and extending vertically to an upper surface of the MEMS layer;
a redistribution layer including a plurality of conductive paths extending laterally across a horizontal portion of the MEMS layer, each of the conductive paths connected to one of the plurality of electrical connections;
a plurality of solderable pads defining external solderable contact points, each of the plurality of solderable pads connected to one of the plurality of conductive paths such that a first solderable pad of the plurality of solderable pads receives the processed signal; and
an overmold encapsulating the MEMS layer, the processing layer, and the plurality of electrical connections, wherein an upper surface of each solderable pad of the plurality of solderable pads is exposed, thereby forming a package surface configured to bond directly to corresponding pads of an external device.

2. The MEMS device of claim 1, wherein the overmold encapsulates the redistribution layer.

3. The MEMS device of claim 1, wherein the plurality of solderable pads extend beyond an upper surface of the redistribution layer.

4. The MEMS device of claim 1, further comprising a first insulating layer disposed over the MEMS layer and the processing layer, the first insulating layer conforming to horizontal and vertical surfaces of the MEMS layer and the processing layer and including openings exposing each of the plurality of bond pads.

5. The MEMS device of claim 4, wherein each of the plurality of electrical connections is part of the redistribution layer and extends along a vertical sidewall defined by the first insulating layer.

6. The MEMS device of claim 4, wherein the overmold includes a plurality of vias housing the plurality of electrical connections.

7. The MEMS device of claim 4, further comprising a second insulating layer disposed over the redistribution layer, the second insulating layer patterned with openings exposing regions of the redistribution layer for connection with the plurality of solderable pads.

8. The MEMS device of claim 1, wherein the MEMS layer includes a peripheral extension overlying the plurality of bond pads and having a plurality of vias extending vertically therethrough providing passages to the plurality of bond pads, each of the plurality of electrical connections extending through one of the plurality of vias.

9. The MEMS device of claim 8, further comprising a first insulating layer disposed over the MEMS layer and conforming to horizontal and vertical surfaces of the MEMS layer and lining surfaces of the plurality of vias.

10. The MEMS device of claim 9, wherein the redistribution layer extends laterally across the horizontal portion of the first insulating layer.

11. The MEMS device of claim 9, further comprising a second insulating layer disposed over the redistribution layer, the second insulating layer patterned with openings exposing regions of the redistribution layer for connection with the plurality of solderable pads.

12. The MEMS device of claim 1, wherein the MEMS layer includes a MEMS handle and an actuator layer including the at least one movable MEMS component.

13. The MEMS device of claim 1, wherein the package surface formed by the upper surface of each solderable pad of the plurality of solderable pads is a substantially planar package surface.

14. A method for fabricating a microelectromechanical sensor (MEMS) device, comprising:
providing a processing layer including processing circuitry and a plurality of bond pads that each receive a processed signal from the processing circuitry;
coupling a MEMS layer to the processing layer, the MEMS layer defining a cavity including at least one movable MEMS component;
forming a plurality of electrical connections, each electrical connection extending from a respective one of the plurality of bond pads vertically to an upper surface of the MEMS layer;
forming a redistribution layer on the upper surface of the MEMS layer, the redistribution layer including a plurality of conductive paths extending laterally across a horizontal portion of the MEMS layer and each of the conductive paths connected to one of the plurality of electrical connections;
forming a plurality of solderable pads on the redistribution layer, the solderable pads defining external solderable contact points and each connected to one of the plurality of conductive paths;
forming an overmold encapsulating the MEMS layer and the processing layer, with an upper surface of the plurality of solderable pads exposed; and
planarizing an upper surface of the overmold to form a package surface for the overmold and solderable pads for direct mounting to external circuitry.

15. The method of claim 14, wherein forming an overmold encapsulating the MEMS layer and the processing layer includes encapsulating the redistribution layer.

16. The method of claim 14, wherein forming the plurality of solderable pads on the redistribution layer includes forming the solderable pads on an upper surface of the redistribution layer.

17. The method of claim 14, further comprising forming a first insulating layer over the MEMS layer and the processing layer after the coupling, the first insulating layer conforming to horizontal and vertical surfaces of the MEMS layer and the processing layer and including openings exposing each of the plurality of bond pads.

18. The method of claim 17, wherein the plurality of electrical connections are formed as part of the redistribution layer and extend along a vertical sidewall defined by the first insulating layer.

19. The method of claim 17, further comprising forming a plurality of vias in the overmold, wherein the plurality of electrical connections are formed in the plurality of vias.

20. The method of claim 17, further comprising forming a second insulating layer over the redistribution layer and patterning the second insulating layer with openings exposing regions of the redistribution layer for connection with the solderable pads.

21. The method of claim 14, wherein forming the plurality of electrical connections includes forming the plurality of electrical connections as continuous vertical portions of the redistribution layer extending from the plurality of bond pads to an upper surface of the MEMS layer.

22. The method of claim 14, further comprising forming a plurality of vias extending vertically through a peripheral extension of the MEMS layer overlying the plurality of bond pads, and forming the plurality of electrical connections by metallizing the vias to electrically connect the plurality of bond pads to the redistribution layer, wherein the plurality of bond pads are aligned in a row and the plurality of vias are arranged in a row aligned with the plurality of bond pads.

23. The method of claim 22, further comprising etching an upper surface of the MEMS layer after the coupling and filling the etched openings with conductive material to form the redistribution layer.

24. The method of claim 14, wherein each of the plurality of solderable pads includes an underbump metallization.

25. The method of claim 14, further comprising forming a first insulating layer over the MEMS layer and the processing layer after the coupling, forming the redistribution layer on the first insulating layer, forming a second insulating layer on the redistribution layer, forming each of the plurality of solderable pads on the redistribution layer after the forming the second insulating layer, and forming the overmold on the second insulating layer after forming the second insulating layer.

26. A method for fabricating a microelectromechanical sensor (MEMS) device, comprising:
providing a processing layer including processing circuitry and a plurality of bond pads that each receive a processed signal from the processing circuitry;
coupling a MEMS layer to the processing layer, the MEMS layer defining a cavity including at least one movable MEMS component;
forming an overmold encapsulating the MEMS layer and the processing layer;
forming vias through the overmold and providing access to the plurality of bond pads;
forming a plurality of electrical connections, each electrical connection extending from a respective one of the plurality of bond pads vertically through a respective one of the vias to an upper surface of the overmold;
forming a redistribution layer on the upper surface of the overmold, the redistribution layer including a plurality of conductive paths extending laterally across a horizontal portion of the overmold and each of the conductive paths connected to one of the plurality of electrical connections; and
forming a plurality of solderable pads on the redistribution layer, the solderable pads defining external solderable contact points and each connected to one of the plurality of conductive paths.
